(19) United States
(12) Patent Application Publication
(10) Pub. No.: US 2018/0312975 A1
(43) Pub. Date: Nov. 1, 2018

(54) METHODS AND APPARATUSES FOR DEPOSITION OF ADHERENT CARBON COATINGS ON INSULATOR SURFACES

(71) Applicant: Adela Bardosova, (US)

(72) Inventors: Hana Baránková, Uppsala (SE); Ladislav Bardos, Uppsala (SE)

(21) Appl. No.: 15/853,018

(22) Filed: Dec. 22, 2017

(30) Foreign Application Priority Data
Dec. 27, 2016 (SE) 1651742-7

(51) Int. Cl. C23C 16/50; H01J 37/32; H01J 37/34; C23C 14/06; C23C 14/34; C23C 14/02; C23C 16/26; C23C 16/02

(52) U.S. Cl. CPC C23C 16/50; H01J 37/32596; H01J 37/3455; H01J 37/3244; H01J 37/3255; H01J 2237/332; C23C 14/34; C23C 14/02; C23C 16/26; C23C 16/02; H01J 2237/3321; C23C 14/0605

(57) ABSTRACT

Deposition of adherent carbon coating(s) on insulator surface(s) can include pretreatment of the insulator surface(s) in a pretreatment plasma (15) generated by a second power generator (11) in an auxiliary magnetic field in a second gas (14), and deposition of carbon coatings onto pretreated insulator surface(s) with the aid of a hollow cathode. The deposition onto the pretreated insulator surface(s) can include deposition by PVD from the hollow cathode simultaneously with PE CVD in a hollow cathode plasma (16) generated in a second gas (13). The second gas 13 can comprise one or more hydrocarbons. The insulator surfaces can include glass or ceramics.

### CROSS-REFERENCE TO RELATED APPLICATIONS

This application claims the benefit of prior filed Swedish Patent Application No. 1651742-7, filed Dec. 27, 2016, which is hereby incorporated by reference herein in its entirety.

### BACKGROUND

Majority of carbon deposition methods based on gas discharge plasma require high vacuum below about 0.01 Torr, which requires expensive high-vacuum pumps. Such methods utilize sputtering of carbon targets by bombarding by high-energy positive ions in so-called physical vapor deposition (PVD) process, mostly in magnetron arrangements. Another kind of methods utilizes reactive carbon based species to deposit on substrates in plasmas containing hydrocarbon components. These methods are referred to as plasma enhanced chemical vapor deposition (PE CVD) and require vacuum below about 0.01 Torr, too. There are, however, film deposition methods utilizing so-called hollow cathodes, where the active plasma can be generated up to atmospheric gas pressure and even higher. Very dense hollow cathode plasmas, both at low and high gas pressures, can be generated in cathodes utilizing auxiliary magnetic fields focusing the plasma at the outlet of the cathode hole. Linear magnetized hollow cathodes were disclosed by L. Bardos et al. in U.S. Pat. No. 5,908,602 and by H. Barankova et al. in U.S. Pat. No. 6,351,075.

Depending on their properties (hardness, thickness, structure, electrical conductivity) carbon-based coatings allow a number of applications. However, a general problem in deposition of carbon coatings on insulator substrates, like glass and ceramics, is their poor adhesion to the surface. For certain applications this problem can be solved using different interface films, for example thin tungsten, aluminum or silicon films. Without such interface films the adhesion is unsatisfactory. However, the interface film changes surface properties of the substrate and for some applications cannot be used.

Influence of a silicon interlayer was investigated in D. A. L. Oliveira et al., “Influence of the silicon interlayer on diamond-like carbon films,” Revista Univap, Sao Jose dos Campos-SP, 18, 112 (2012). In U.S. Patent Pub. No. 2004/0028906 entitled “Diamond-like carbon coating on glass and plastic for added hardness and abrasion resistance,” J. C. Anderson et al. disclose a non-metallic article that has been coated with a diamond-like carbon (DLC) coating. In V. S. Veerasamy et al., “Diamond-like amorphous carbon coatings for large areas of glass,” Thin Solid Films, 442, 1 (2003), large area deposition of DLC, with sp³ content as high as 80%, directly onto 1.5 m wide glass substrates is reported. In U.S. Pat. No. 6,303,226 entitled “Highly tetrahedral amorphous carbon coating on glass” V. S. Veerasamy discloses a soda inclusive glass substrate coated with a highly tetrahedral amorphous carbon inclusive layer that is a form of diamond-like carbon (DLC). Effects of plasma treatment on adhesion of sputter deposited amorphous carbon thin films to glass were investigated in S. Takeda et al., “Improved adhesion of amorphous carbon thin films on glass by plasma treatment,” J. Vac. Sci. Technol., A22, 1297 (2004). Amorphous carbon coatings prepared using rf powered cylindrical and linear hollow cathodes were reported in H. Barankova et al., “Amorphous Carbon Films on Glass Prepared by Hollow Cathodes at Moderate Pressure,” ECS Journal of Solid State Science and Technology, 5 (9) N57-N60 (2016).

### SUMMARY

Recognizing that a need remains for an improved approach to overcome, for example, the drawbacks described above, the present disclosure provides methods and apparatuses for deposition of adherent carbon coatings on insulator surfaces.

An aspect of the present invention provides a method of deposition, comprising: in a first phase, performing a plasma pretreatment of a surface of an insulator substrate positioned on a substrate holder in a pretreatment plasma generated by a second power generator coupled (e.g., electrically connected) to the substrate holder in an auxiliary magnetic field of at least about 0.01 Tesla generated by magnets in a second gas, thereby forming a pretreated surface of the insulator substrate; and in a second phase, using a hollow cathode coupled (e.g., electrically connected) to a first power generator to deposit a carbon coating on the pretreated surface of the insulator substrate by at least one of physical vapor deposition (PVD) from the hollow cathode and plasma enhanced chemical vapor deposition (PE CVD) from a hollow cathode plasma generated in a first gas comprising one or more hydrocarbons and flowing through the hollow cathode, thereby forming an adherent carbon coating on the surface of the insulator substrate. The insulator substrate can be positioned on a shielding on the substrate holder to shield a surface of the substrate holder from the pretreatment plasma and/or from the hollow cathode plasma. The insulator substrate can be glass or a ceramic. In some cases, the method further comprises depositing the carbon coating on the pretreated surface of the insulator substrate by the PVD and the PE CVD. The PVD and the PE CVD can be simultaneous. The hollow cathode can be coupled (e.g., electrically connected) to the first power generator by a first power switch. The second power generator can be coupled (e.g., electrically connected) to the substrate holder by a second power switch. In some cases, the method further comprises providing AC power from the second power generator to the substrate holder. In some cases, the method further comprises providing AC power having a frequency higher than about 1 kHz from the second power generator. In some cases, the method further comprises providing DC, pulsed DC, AC, pulsed AC, radio frequency or pulsed radio frequency power from the first power generator. The plasma pretreatment can create unsaturated bonds of surface atoms on the insulator substrate. The surface atoms can include silicon, aluminum, or any combination thereof. The hollow cathode can be a graphite hollow cathode. The PVD can comprise depositing carbon particles from the graphite hollow cathode on the insulator substrate. The insulator substrate can be part of a plurality of insulator substrates, and the plurality of insulator substrates can be positioned on the substrate holder and subjected to the first and second phases of the method. The second phase can be continued until the adherent carbon coating has a coating thickness of greater than or equal to about 0.01 micrometers. In some cases, the method further comprises maintaining a total gas pressure (e.g., of the first gas and the second gas) greater than about 0.01 Torr.

Another aspect of the present invention provides an apparatus for deposition, comprising (a) a chamber containing a substrate holder holding one or more insulator substrates, and at least one hollow cathode, and (b) magnets, wherein the apparatus is configured to deposit an adherent carbon coating on a surface of an insulator substrate among the one or more insulator substrates by implementing a method comprising: in a first phase, performing a plasma pretreatment of a surface of the insulator substrate on the substrate holder in a pretreatment plasma generated by a second power generator coupled (e.g., electrically connected) to the substrate holder in an auxiliary magnetic field of at least about 0.01 Tesla generated by the magnets in a second gas admitted into the chamber, thereby forming a pretreated surface of the insulator substrate; and in a second phase, using the at least one hollow cathode coupled (e.g., electrically connected) to a first power generator to deposit a carbon coating on the pretreated surface of the insulator substrate by at least one of physical vapor deposition (PVD) from the at least one hollow cathode and plasma enhanced chemical vapor deposition (PE CVD) from a hollow cathode plasma generated in a first gas comprising one or more hydrocarbons and flowing into the chamber through the at least one hollow cathode, thereby forming the adherent carbon coating on the surface of the insulator substrate. The at least one hollow cathode can include a graphite hollow cathode. In some cases, the apparatus further comprises rotatable magnets configured to generate a magnetic field in which the at least one hollow cathode is positioned. In some cases, the rotatable magnets can be removed. The substrate holder can be arranged with the magnets creating the auxiliary magnetic field at surfaces of the one or more insulator substrates. The magnets can be embedded in the substrate holder. The substrate holder can be connected to the second power generator by a second power switch to generate the pretreatment plasma on surfaces of the one or more insulator substrates. The pretreatment plasma can be generated in the second gas admitted into the chamber. The at least one hollow cathode can face the one or more insulator substrates and be connected to the first power generator by a second power switch to generate the hollow cathode plasma in the first gas. At least a portion of the first gas can be admitted into the chamber through the hollow cathode. The hollow cathode plasma can comprise (i) carbon particles from the graphite hollow cathode, and/or (ii) hydrogen and/or carbon atoms and/or molecules and/or hydrocarbon radicals in neutral, ionized and/or excited states from the first gas. The chamber can be pumped by one or more mechanical pumps. The second gas can comprise at least one noble gas. The second gas can comprise argon, neon, krypton, xenon, helium, hydrogen, or any combination thereof. At least a portion of the second gas can be admitted into the chamber through the hollow cathode. The hollow cathode can be coupled (e.g., electrically connected) to the first power generator by a first power switch. The second power generator can be coupled (e.g., electrically connected) to the substrate holder by a second power switch. The second power generator can be configured to generate AC power. The second power generator can be configured to generate AC power having a frequency higher than about 1 kHz. The first power generator can be configured to generate DC, pulsed DC, AC, pulsed AC, radio frequency or pulsed radio frequency power. The first gas can be composed of a mixture of at least one noble gas with acetylene, methane, ethane and/or one or more other volatile hydrocarbons. The first gas can comprise argon, neon, krypton, xenon, helium, acetylene, methane, ethane, propane, butane, ethylene, propylene, or any combination thereof. The at least one hollow cathode can form a system shaped to follow surface geometry of the one or more insulator substrates. The at least one hollow cathode can include several hollow cathodes. The substrate holder can be configured to perform one or more motions with respect to the hollow cathode. The one or more motions can include linear motion, rotational motion, stepwise motion, or any combination thereof.

Another aspect of the present invention provides a method of deposition, comprising, at a total gas pressure greater than about 0.01 Torr: pretreating a surface of an insulator substrate on a substrate holder in a pretreatment plasma generated by a second power generator coupled (e.g., electrically connected) to the substrate holder in an auxiliary magnetic field generated by magnets, thereby forming a pretreated surface of the insulator substrate; and using a hollow cathode coupled (e.g., electrically connected) to a first power generator to deposit a carbon coating on the pretreated surface of the insulator substrate, thereby forming an adherent carbon coating on the surface of the insulator substrate. The total gas pressure can be maintained in a vacuum chamber. The insulator substrate can be part of a plurality of insulator substrates on the substrate holder. In some cases, the method further comprises: pretreating surfaces of the plurality of insulator substrates on the substrate holder in the pretreatment plasma, thereby forming pretreated surfaces of the plurality of insulator substrates; and using the hollow cathode to deposit carbon coatings on the pretreated surfaces of the plurality of insulator substrates. In some cases, the method further comprises using the hollow cathode to generate a hollow cathode plasma. The auxiliary magnetic field can be at least about 0.01 Tesla.

Another aspect of the present invention provides a method of deposition, comprising depositing, at a total gas pressure greater than about 0.01 Torr, an adherent carbon coating on a surface of an insulator substrate by (a) pretreating the surface of the insulator substrate in a pretreatment plasma, and (b) using a DC, pulsed DC, AC, pulsed AC or pulsed radio frequency hollow cathode to deposit carbon material on the surface of the insulator substrate, wherein the adherent carbon coating has a thickness greater than or equal to about 0.01 micrometer. The total gas pressure can be maintained in a vacuum chamber. The insulator substrate can be part of a plurality of insulator substrates on the substrate holder. In some cases, the adherent carbon coating is capable of withstanding a critical load corresponding to complete coating failure of greater than or equal to about 5 Newton (N). In some cases, the adherent carbon coating is capable of withstanding a critical load corresponding to complete coating failure of greater than or equal to about 20 N. In some cases, the adherent carbon coating is capable of withstanding a critical load corresponding to complete coating failure of greater than or equal to about 50 N.

Another aspect of the present invention relates to a carbon coating on an insulator surface, comprising greater than or equal to about 95% carbon (C) by weight, mole or volume, wherein the carbon coating is capable of withstanding a critical load corresponding to complete coating failure of greater than 50 Newton (N) at a coating thickness of greater than or equal to about 0.5 micrometer on the insulator surface. In some cases, the carbon coating is capable of withstanding the critical load corresponding to complete coating failure when the coating thickness is greater than or equal to about 1 micrometer. In some cases, the carbon coating is capable of withstanding the critical load corresponding to complete coating failure when the coating thickness is greater than or equal to about 20 micrometers. In some cases, the carbon coating is capable of withstanding the critical load corresponding to complete coating failure when the coating thickness is greater than or equal to about 50 micrometers. In some cases, the critical load corresponding to complete coating failure is greater than or equal to about 60 N at the coating thickness. In some cases, the critical load corresponding to complete coating failure is greater than or equal to about 100 N at the coating thickness.

Another aspect of the present invention provides a method of deposition of adherent carbon coatings on insulator surfaces, particularly on glass or ceramics, at gas pressure higher than about 0.01 Torr, wherein in a first phase a pretreatment of the insulator surfaces forms unsaturated bonds of surface atoms, particularly silicon or aluminum, in a plasma generated by an AC power in an auxiliary magnetic field of at least about 0.01 Tesla in at least one noble gas, followed by a second phase of deposition of carbon coatings onto pretreated surfaces by PVD of carbon particles from graphite hollow cathode simultaneously with PE CVD in a hydrocarbon-containing plasma.

Another aspect of the present invention provides an apparatus for application of a method for deposition of adherent carbon coatings on insulator surfaces, particularly on glass or ceramics, in a chamber pumped by mechanical pumps, where the chamber contains insulator substrates on a substrate holder arranged with auxiliary magnets and connected to a second power generator which delivers an AC power and generates an AC pretreatment plasma on substrate surfaces in an auxiliary magnetic field, and at least one graphite hollow cathode connected to a first power generator; and a hydrocarbon-containing gas is admitted into the chamber through the hollow cathode to form a hollow cathode plasma containing carbon particles from the hollow cathode as well as hydrogen and/or carbon atoms and/or molecules and/or hydrocarbon radicals in neutral, ionized and/or excited states.

Another aspect of the present invention provides a method of deposition of adherent carbon coatings on surfaces of insulator substrates, particularly on glass or ceramics, at gas pressure higher than about 0.01 Torr in a chamber, wherein in a first phase a plasma pretreatment of surfaces of the insulator substrates on a substrate holder creates unsaturated bonds of surface atoms, particularly silicon or aluminum, on the insulator substrates in a pretreatment plasma generated by a second power generator delivering an AC power to the substrate holder in an auxiliary magnetic field of at least about 0.01 Tesla generated by magnets in at least one second gas, and in a second phase a deposition of carbon coatings is performed on pretreated surfaces of the insulator substrates using a graphite hollow cathode, coupled (e.g., electrically connected) to a first power generator by a switch for the first power, by physical vapor deposition (PVD) where carbon particles from the graphite hollow cathode are depositing on the insulator substrates, simultaneously with plasma enhanced chemical vapor deposition (PE CVD) from a hydrocarbon-containing hollow cathode plasma generated in a first gas containing hydrocarbons and flowing through the graphite hollow cathode. The chamber can be a vacuum chamber. The first gas can comprise at least one noble gas. The insulator substrates can be positioned on a shielding on the substrate holder to shield the surface of the substrate holder from the pretreatment plasma or from the hydrocarbon-containing hollow cathode plasma. An apparatus for application of the method of deposition of adherent carbon coatings on surfaces of insulator substrates, particularly on glass or ceramics, in the chamber can be pumped by one or more mechanical pumps, contain the substrate holder holding the insulator substrates, and contain the graphite hollow cathode in a magnetic field generated by rotatable magnets. The substrate holder can be arranged with magnets creating the auxiliary magnetic field of at least about 0.01 Tesla at surfaces of the insulator substrates. The substrate holder can be connected to the second power generator by a switch for the second power to generate the pretreatment plasma on the surfaces of the insulator substrates. The pretreatment plasma can be generated in at least one noble gas admitted into the chamber. At least one graphite hollow cathode facing the insulator substrates can be connected to the first power generator by the switch for the first power to generate the hydrocarbon-containing hollow cathode plasma in the hydrocarbon-containing second gas. The second gas can be admitted into the chamber through the graphite hollow cathode. The hydrocarbon-containing hollow cathode plasma can comprise (e.g., be composed of (or from)) carbon particles from (e.g., formed by) the graphite hollow cathode and from hydrogen and/or carbon atoms and/or molecules and/or hydrocarbon radicals in neutral, ionized and/or excited states (e.g., formed from the first gas). The second gas can be a mixture which contains argon, neon and/or helium. At least part of the second gas can be admitted through the graphite hollow cathode. AC power from the second power generator can have a frequency higher than about 10 MHz. The first power generator can generate DC, pulsed DC, AC, pulsed AC, radio frequency or pulsed radio frequency power. The first gas can comprise (e.g., be composed of) a mixture of at least one noble gas with acetylene, methane or other volatile hydrocarbons. The rotatable magnets can be removed. The graphite hollow cathode or several cathodes (e.g., graphite hollow cathodes) can form a system shaped to follow surface geometry of the insulator substrates. The substrate holder can perform linear, rotational, stepwise, or other combined motions with respect to the graphite hollow cathode. The magnets can be embedded into the substrate holder.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” and “FIGs.” herein), of which:

FIG. 1 is a schematic view of an example of an apparatus for application of a method of deposition of, for example, adherent carbon coatings on surfaces of insulator substrates.

FIG. 2a is a schematic view of an example of an apparatus for application of a method of deposition of, for example, adherent carbon coatings on surfaces of insulator substrates in a surface pretreatment phase of the method according to this invention.

FIG. 2b is a schematic view of an example of an apparatus for application of a method of deposition of, for example, adherent carbon coatings on surfaces of insulator substrates in a hollow cathode deposition of carbon films in a second phase of the method according to this invention.

FIG. 3 is a schematic view of an example of an apparatus for application of a method of deposition of, for example, adherent carbon coatings on surfaces of insulator substrates, where rotatable magnets at the hollow cathode are removed.

FIG. 4 is a schematic view of an example of an apparatus for application of a method of deposition of, for example, adherent carbon coatings on surfaces of insulator substrates, where a hollow cathode or several hollow cathodes form a system shaped to follow surface geometry of an insulator substrate.

FIG. 5 is a schematic view of an example of an apparatus for application of a method of deposition of, for example, adherent carbon coatings on surfaces of insulator substrates, where a rotatable substrate holder contains a system of embedded magnets.

### DETAILED DESCRIPTION

Provided herein are methods and apparatuses for deposition of, for example, adherent carbon coatings on surfaces of insulator substrates (e.g., particularly on glass or ceramics, at gas pressure higher than about 0.01 Torr in a vacuum chamber, where simple mechanical pumps are sufficient to maintain the gas pressure). The methods described in the present disclosure are based on two subsequent phases, plasma pretreatment and plasma-assisted deposition of carbon coating. During plasma pretreatment the surface atoms on insulator substrates may acquire unsaturated bonds, which may lead to high surface reactivity and/or enhanced bonding with carbon particles formed during plasma deposition of carbon coatings in a dense hollow cathode generated plasma. The adherent carbon films can reach thicknesses of even more than ten micrometers, which is almost impossible without interface films in other methods. An additional advantage of the methods described herein is deposition by the hollow cathode plasma, which produces typically high density of charged particles and can perform very high rate of both PVD and PE CVD processes. Use of magnetic field causes better confinement of the plasma with reduced loss of charged particles. For the sake of purity of the coated films the interactions of plasmas with the substrate holder can be avoided or minimized in both pretreatment and deposition phases of the methods according to this invention. The substrate holder with substrates, the hollow cathodes or both can be moved with respect to each other, which can provide better uniformity of coating process. It is also possible to apply the pretreatment phase and the deposition phase of the present disclosure simultaneously, using an in-line arrangement of the plasma system with successively moving substrates on a moving holder. The substrate holder can also be provided with cooling and/or heating means.

Various aspects of the invention described herein may be applied to any of the particular applications set forth below or in any other type of plasma processing including, but not limited to combinations of several apparatuses according to this invention, or combinations with other types of plasma systems, such as, for example, with microwave plasma systems for plasma pretreatments and for assistance in carbon coating, or with arc evaporators, laser plasma sources, etc. The methods and systems described herein may be applied as a standalone method or system, or as part of an integrated processing system. It shall be understood that different aspects of the invention can be appreciated individually, collectively, or in combination with each other.

Adherent carbon coatings (also “adherent carbon films” herein) described herein may refer to carbon coatings comprising primarily carbon (e.g., greater than or equal to about 85%, 90%, 95%, 96%, 97%, 98%, 99%, 99.5% or 99.9% carbon (C) content by weight, mole or volume). Such carbon coatings may comprise less than or equal to about 15%, 10%, 5%, 4%, 3%, 2%, 1%, 0.5% or 0.1% of an individual non-carbon material or of non-carbon materials in total (e.g., by weight, mole or volume). Further, such carbon coatings can display improved adherence (e.g., as measured by scratch tests performed, for example, by an indenter in progressive load mode, and analyzed using, for example, an optical microscope). For example, the carbon coatings described herein may withstand critical loads related to first damage(s) and/or to a complete coating failure of greater than or equal to about 1 Newton (N), 2 N, 5 N, 10 N, 15 N, 20 N, 25 N, 30 N, 35 N, 40 N, 45 N, 50 N, 55 N, 60 N, 65 N, 70 N, 75 N, 80 N, 85 N, 90 N, 95 N, 100 N, 110 N, 120 N, 130 N, 140 N 150 N, 160 N, 170 N, 180 N, 190 Nor 200 N. The adherent carbon coatings described herein may display such adherences at a thickness of greater than or equal to about 0.01 micrometer, 0.05 micrometer, 0.1 micrometer, 0.5 micrometer, 1 micrometer, 2 micrometers, 3 micrometers, 4 micrometers, 5 micrometers, 6 micrometers, 7 micrometers, 8 micrometers, 9 micrometers, 10 micrometers, 12 micrometers, 14 micrometers, 16 micrometers, 18 micrometers, 20 micrometers, 22 micrometers, 24 micrometers, 26 micrometers, 28 micrometers, 30 micrometers, 35 micrometers, 40 micrometers, 45 micrometers, 50 micrometers, 55 micrometers, 60 micrometers, 65 micrometers, 70 micrometers or 75 micrometers.

Reference will now be made to the drawings. Throughout the drawings, the same reference numbers refer to similar or corresponding elements or parts. It will be appreciated that the drawings and features therein are not necessarily drawn to scale.

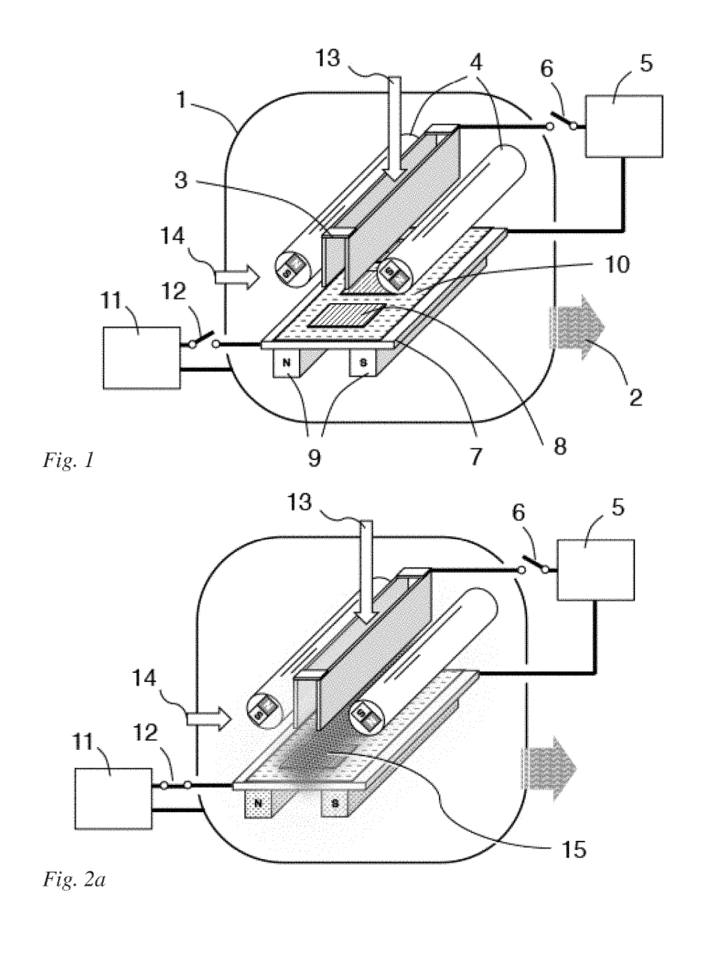

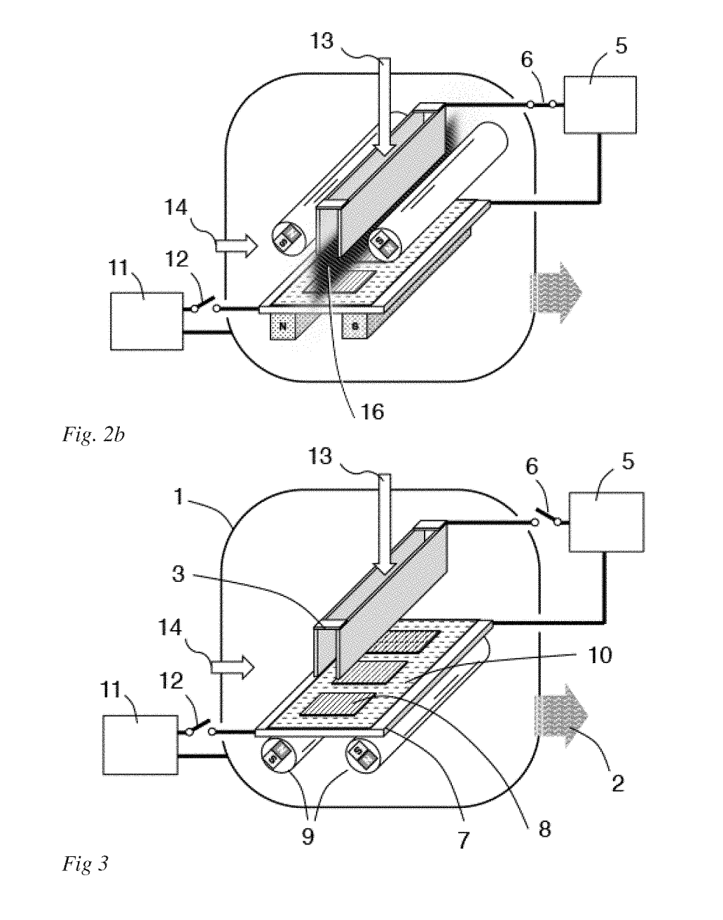

Referring to FIGS. 1, 2a and 2b, an example of an apparatus for application of a method of deposition (e.g., at gas pressure higher than about 0.01 Torr) of adherent carbon coatings on surfaces of insulator substrates (e.g., particularly on glass or ceramics) in accordance with the present invention is described. The apparatus can comprise a chamber (e.g., vacuum chamber or hermetic chamber) 1. The chamber 1 may be pumped by one or more mechanical pumps 2 to a given gas pressure (e.g., total gas pressure). For example, the chamber 1 may be pumped by the one or more mechanical pumps 2 to a gas pressure of at least about 0.01 Torr. The apparatus comprises (e.g., the chamber 1 contains) a substrate holder 7 with insulator substrates 8, and a hollow cathode (e.g., graphite hollow cathode) 3 in a magnetic field generated by rotatable magnets 4. The insulator substrates 8 can be positioned on or carried by the substrate holder 7. The hollow cathode 3 can have an opening or outlet oriented toward the insulator substrates 8. The rotatable magnets 4 can be provided on opposite lateral sides of the hollow cathode 3. The substrate holder 7 can be movable (e.g., linearly) with respect to the hollow cathode 3. Moving members (not shown) may therefore be provided for moving any one or both of the substrate holder 7 and the hollow cathode 3. The holder 7 can be arranged with magnets 9 that create an auxiliary magnetic field of at least about 0.01 Tesla at surfaces (e.g., upper surfaces) of the insulator substrates 8. The magnets 9 may be provided, for example, adjacent to or as part of (e.g., embedded in) the holder 7. The holder 7 can be provided with cooling and/or heating means (not shown). The holder 7 is electrically connected to a second power generator 11 by a switch for the second power (also “second power switch” herein) 12 for generation of a pretreatment plasma 15 on the surfaces of the insulator substrates 8. The pretreatment plasma 15 is generated in at least one second gas 14 provided to the apparatus (e.g., admitted into the chamber 1). The apparatus comprises (e.g., the chamber 1 contains) at least one hollow cathode (e.g., graphite hollow cathode) 3 facing the insulator substrates 8. The cathode 3 is connected to a first power generator 5 by a switch for the first power (also “first power switch” herein) 6 to generate a hydrocarbon-containing hollow cathode plasma 16 in a hydrocarbon-containing first gas 13 provided to the apparatus (e.g., admitted into the chamber 1) through the hollow cathode (e.g., graphite hollow cathode) 3. The hydrocarbon-containing hollow cathode plasma 16 may be composed of carbon particles formed from the hollow cathode (e.g., graphite hollow cathode) 3, of hydrogen and/or carbon atoms and/or molecules and/or hydrocarbon radicals in neutral, ionized and/or excited states (e.g., formed from the first gas 13), or of any combination thereof. In the pretreatment phase of the methods described herein the second gas 14 for the pretreatment plasma 15 can be provided to the apparatus (e.g., admitted into the chamber 1) by a separate inlet or through the hollow cathode (e.g., graphite hollow cathode) 3 (e.g., instead of the first gas 13), or in parts using both ways. The second gas 14 admitted through each inlet may or may not be the same. The second gas (e.g., an individual second gas among several second gases) 14 can comprise one or more noble gases (e.g., argon, neon, krypton, xenon, and/or helium), hydrogen, or any combination thereof. The second gas 14 can be a mixture (e.g., a mixture containing one or more noble gases, hydrogen, or any combination thereof). The second gas 14 can comprise, for example, hydrogen, argon and/or other noble gases. The second gas 14 can comprise, for example, argon, neon, krypton, xenon, helium, hydrogen, or any combination thereof. For plasma pretreatment of insulator substrates 8 the second power generator 11 can deliver an AC power preferably with a frequency higher than about 1 kilohertz (kHz), 10 kHz, 100 kHz, 250 kHz, 500 kHz, 750 kHz, 1 megahertz (MHz), 5 MHz or 10 MHz. The first power generator 5 for generation of hydrocarbon-containing hollow cathode plasma 16 in the hollow cathode (e.g., graphite hollow cathode) 3 can be configured to generate DC, pulsed DC, AC, pulsed AC, radio frequency or pulsed radio frequency power.

Referring to FIG. 2a, an example of a first phase of the method of deposition of adherent carbon coatings on surfaces of insulator substrates (e.g., particularly on glass or ceramics) is described. In the first phase (also “pretreatment phase” herein) a plasma pretreatment of surfaces of the insulator substrates 8 on the substrate holder 7 can create unsaturated bonds of surface atoms, particularly silicon or aluminum, on the insulator substrates 8 in the pretreatment plasma 15 generated by the second power generator 11 delivering an AC power to the substrate holder 7 in an auxiliary magnetic field of at least about 0.01 Tesla generated by the magnets 9 in the at least one second gas 14. In this first phase the second power generator 11 is connected to the substrate holder 7 by the switch for the second power 12, and the first power generator 5 is disconnected from the hollow cathode (e.g., graphite hollow cathode) 3. To avoid possible contamination of surfaces of the insulator substrates 8 by particles from the substrate holder 7 during pretreatment in the pretreatment plasma 15, for example by sputtering of the surface of the substrate holder 7, the insulator substrates 8 can be positioned on a shielding 10 on the substrate holder 7 to shield the surface of the substrate holder 7 from the pretreatment plasma 15. The shielding (also “shielding on the substrate holder” herein) 10 can comprise or be of the same material as the insulator substrates 8 and/or one or more other suitable materials (e.g., any other material capable of preventing release of and/or contamination by particles from the substrate holder 7).

Referring to FIG. 2b, an example of a second phase of the method of deposition of adherent carbon coatings on surfaces of insulator substrates (e.g., particularly on glass or ceramics) is described. In the second phase (also “deposition phase” herein) a deposition of carbon coatings is performed on pretreated surfaces (e.g., the upper surfaces) of the insulator substrates 8 using the hollow cathode (e.g., graphite hollow cathode) 3 connected to the first power generator 5 by the switch for the first power 6, by, for example, physical vapor deposition (PVD) where carbon particles from the hollow cathode (e.g., graphite hollow cathode 3) are depositing (e.g., forming a coating) on the insulator substrates 8, simultaneously with plasma enhanced chemical vapor deposition (PE CVD) from the hydrocarbon-containing hollow cathode plasma 16 generated in the first gas 13 containing hydrocarbons and flowing through the hollow cathode (e.g., graphite hollow cathode) 3. The first gas 13 can comprise one or more noble gases, one or more hydrocarbons (e.g., volatile hydrocarbons), or any combination thereof. The first gas 13 can comprise, for example, argon, neon, krypton, xenon, helium, acetylene, methylacetylene, methane, ethane, propane, butane, ethylene, propylene, or any combination thereof. The first gas 13 can be composed of, for example, a mixture of at least one noble gas with acetylene, methane, ethane and/or one or more other volatile hydrocarbons. In the second phase the second power generator 11 is disconnected from the substrate holder 7 by the switch for the second power 12. To avoid possible contamination of growing films on surfaces of the insulator substrates 8 by particles from the substrate holder 7 during deposition in the hydrocarbon-containing hollow cathode plasma 16, for example by sputtering of the surface of the substrate holder 7 or by plasma reactive processes on the holder, the insulator substrates 8 can be positioned on the shielding 10 on the substrate holder 7 to shield the surface of the substrate holder 7 from the plasma 16. The second phase of the method can be started at the end of the first phase, or even before finishing of the first phase. In some cases both phases of the method according to this invention can be carried out simultaneously. In this case the second power generator 11 forms an AC bias on the surfaces of the insulator substrates 8 during deposition of carbon films. The second power generator 11 can deliver less than or equal to about 50% of the power from the first power generator 5.

Referring to FIG. 3, a schematic view of an example of an apparatus for application of a method of deposition of adherent carbon coatings on surfaces of insulator substrates 8 (e.g., particularly on glass or ceramics) in accordance with the present invention is explained. In this example the rotatable magnets 4 at the hollow cathode (e.g., graphite hollow cathode) 3 are removed and the cathode works without variable focusing magnetic field. This example also shows that the magnets 9 can be rotatable magnets in place of stationary magnets. Changes in intensity and geometry of magnetic field (e.g., generated by the magnets 9) can improve uniformity of the plasma pretreatment of substrates 8.

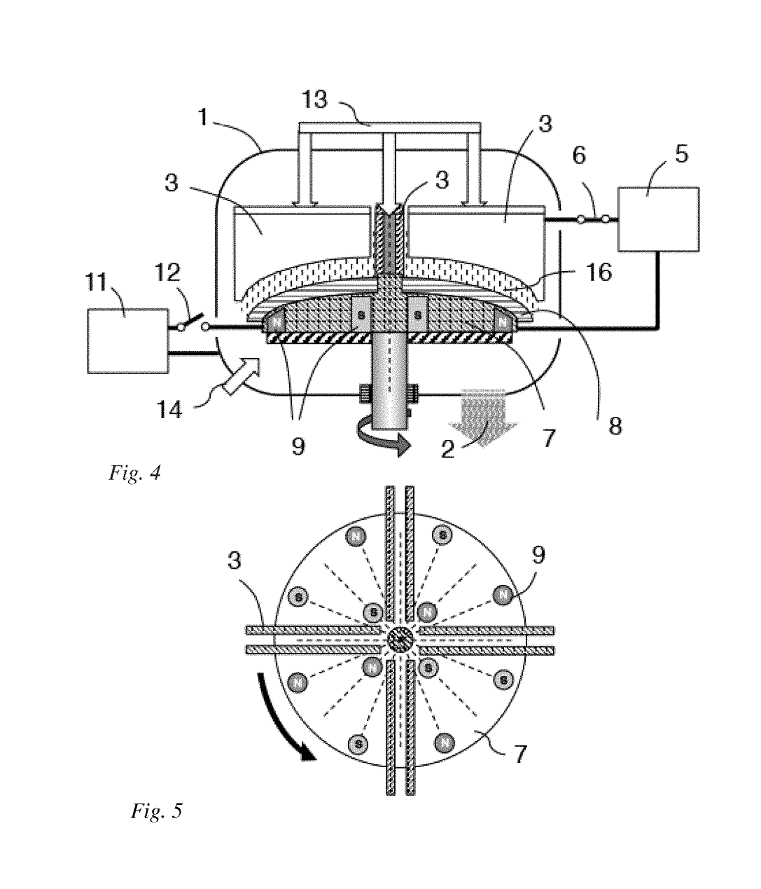

Referring to FIG. 4, a schematic view of another example of an apparatus for application of a method of deposition of adherent carbon coatings on surfaces of insulator substrates 8 (e.g., particularly on glass or ceramics) in accordance with the present invention is explained. This example shows a deposition phase of the method where the apparatus comprises four hollow cathodes (e.g., graphite hollow cathodes) 3 forming a system shaped to follow a curved (e.g., convex up) surface geometry of axially symmetric insulator substrate 8 positioned at substrate holder (also “holder” herein) 7 with geometry adjusted to the shape of the substrate 8. For example, the hollow cathodes may have openings or outlets oriented toward the insulator substrate(s) 8 and the geometry of the openings or outlets may correspond to (e.g., follow) the geometry of the insulator substrate(s) 8. The holder 7 can be rotatable. The holder 7 can be rotated (e.g., around an axis of the substrate holder 7) in order to improve spatial uniformity of at least one (e.g., both) of the pretreatment phase and the deposition phase of the coating process.

Referring to FIG. 5, a schematic view of another example of an apparatus for application of a method of deposition of adherent carbon coatings on surfaces of insulator substrates 8 (e.g., particularly on glass or ceramics) in accordance with the present invention is explained. This example shows a cross-sectional top view of an apparatus with rotatable substrate holder 7 with embedded regularly distributed magnets 9 and with four hollow cathodes (e.g., graphite hollow cathodes) 3 facing the holder. During rotation of the holder 7 the uniformity of both the pretreatment plasma 15 and the hydrocarbon-containing hollow cathode plasma 16 can be improved in both the pretreatment and the deposition phase of the coating process.

Implementations of the methods and apparatuses of the present disclosure can include maintaining a given gas pressure (or range of gas pressures). For example, the gas pressure (e.g., total gas pressure) can be greater than or equal to about 0.01 Torr, 0.02 Torr, 0.05 Torr, 1 Torr, 10 Torr, 50 Torr, 100 Torr, 200 Torr, 300 Torr, 400 Torr, 500 Torr, 600 Torr, 700 Torr, 760 Torr (1 atmosphere (atm)), 1.5 atm, 2 atm, 3 atm, 4 atm or 5 atm. The apparatuses described herein may comprise one or more components provided outside of a chamber. For example, the magnets 9 and/or the rotatable magnets 4 may be provided outside of a chamber. Any aspects of the present disclosure described in relation to such components contained in a chamber may equally apply to such components provided outside (or in absence) of a chamber.

The apparatuses of the present disclosure can comprise greater than or equal to 1, 2, 3, 4, 5, 6, 7, 8, 9, 10, 12, 14, 16, 18, 20, 25, 30, 40 or 50 hollow cathodes (also “cathodes” herein). The hollow cathode(s) (e.g., one hollow cathode or a plurality of hollow cathodes) may be shaped to complex geometries) and/or arranged in pattern(s) (e.g., in an array). The substrate holder may perform linear, rotational, stepwise, or other combined motions with respect to the hollow cathode(s). The hollow cathode(s) may perform linear, rotational, stepwise, or other combined motions with respect to the substrate holder. The substrate holder and the hollow cathode(s) may be movable with respect to each other through linear motion(s), rotational motion(s), stepwise motion(s), or any combination thereof. Such motion(s) may be in one, two or three dimensions (e.g., vertically, horizontally or a combination thereof). Any aspects of the present disclosure described in relation to surfaces of insulator substrates and/or adherent carbon coatings thereon may equally apply to a surface of an insulator substrate and/or an adherent carbon coating thereon, respectively, at least in some configurations, and vice versa.

It is to be understood that the terminology used herein is used for the purpose of describing specific embodiments, and is not intended to limit the scope of the present invention. It should be noted that as used herein, the singular forms of “a”, “an” and “the” include plural references unless the context clearly dictates otherwise. In addition, unless defined otherwise, all technical and scientific terms used herein have the same meaning as commonly understood by one of ordinary skill in the art to which this invention belongs.

While preferable embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

### LIST OF USED REFERENCE NUMBERS

1—chamber
2—pumps
3—hollow cathode
4—rotatable magnets
5—first power generator
6—switch for the first power
7—substrate holder
8—insulator substrate(s)
9—magnets
10—shielding on the substrate holder
11—second power generator
12—switch for the second power
13—first gas
14—second gas
15—pretreatment plasma
16—hydrocarbon-containing hollow cathode plasma

What is claimed is:

1. A method of deposition, comprising:
in a first phase, performing a plasma pretreatment of a surface of an insulator substrate (8) positioned on a substrate holder (7) in a pretreatment plasma (15) generated by a second power generator (11) electrically connected to said substrate holder (7) in an auxiliary magnetic field of at least about 0.01 Tesla generated by magnets (9) in a second gas (14), thereby forming a pretreated surface of said insulator substrate (8); and
in a second phase, using a hollow cathode (3) electrically connected to a first power generator (5) to deposit a carbon coating on said pretreated surface of said insulator substrate (8) by at least one of physical vapor deposition (PVD) from said hollow cathode and plasma enhanced chemical vapor deposition (PE CVD) from a hollow cathode plasma (16) generated in a first gas (13) comprising one or more hydrocarbons and flowing through said hollow cathode (3), thereby forming an adherent carbon coating on said surface of said insulator substrate (8).

2. A method according to claim 1, wherein said insulator substrate (8) is positioned on a shielding (10) on said substrate holder (7) to shield a surface of said substrate holder (7) from said pretreatment plasma (15) and/or from said hollow cathode plasma (16).

3. A method according to claim 1, further comprising depositing said carbon coating on said pretreated surface of said insulator substrate (8) by said PVD and said PE CVD, wherein said PVD and said PE CVD are simultaneous.

4. A method according to claim 1, wherein said plasma pretreatment creates unsaturated bonds of surface atoms on said insulator substrate (8), and wherein said surface atoms include silicon, aluminum, or any combination thereof.

5. A method according to claim 1, further comprising (i) providing AC power having a frequency higher than about 1 kHz from said second power generator, and/or (ii) providing DC, pulsed DC, AC, pulsed AC, radio frequency or pulsed radio frequency power from said first power generator.

6. A method according to claim 1, wherein said second phase is continued until said adherent carbon coating has a coating thickness of greater than or equal to about 0.01 micrometers.

7. A method according to claim 1, wherein said insulator substrate (8) is part of a plurality of insulator substrates (8), and wherein said plurality of insulator substrates (8) are positioned on said substrate holder (7) and subjected to said first and second phases.

8. A method according to claim 1, further comprising maintaining a total gas pressure greater than about 0.01 Torr.

9. A method according to claim 1, wherein said insulator substrate is glass or a ceramic.

10. An apparatus for deposition, comprising (a) a chamber (1) containing a substrate holder (7) holding one or more insulator substrates (8), and at least one hollow cathode (3), and (b) magnets (9), wherein said apparatus is configured to deposit an adherent carbon coating on a surface of an insulator substrate (8) among said one or more insulator substrates (8) by implementing a method comprising:
in a first phase, performing a plasma pretreatment of a surface of said insulator substrate (8) on said substrate holder (7) in a pretreatment plasma (15) generated by a second power generator (11) electrically connected to said substrate holder (7) in an auxiliary magnetic field of at least about 0.01 Tesla generated by said magnets (9) in a second gas (14) admitted into said chamber (1), thereby forming a pretreated surface of said insulator substrate (8); and
in a second phase, using said at least one hollow cathode (3) electrically connected to a first power generator (5) to deposit a carbon coating on said pretreated surface of said insulator substrate (8) by at least one of physical vapor deposition (PVD) from said at least one hollow cathode and plasma enhanced chemical vapor deposition (PE CVD) from a hollow cathode plasma (16) generated in a first gas (13) comprising one or more hydrocarbons and flowing into said chamber (1) through said at least one hollow cathode (3), thereby forming said adherent carbon coating on said surface of said insulator substrate (8).

11. An apparatus according to claim 10, wherein said apparatus further comprises rotatable magnets (4) configured to generate a magnetic field in which said at least one hollow cathode (3) is positioned.

12. An apparatus according to claim 10, wherein (i) said second gas (14) comprises argon, neon, krypton, xenon, helium, hydrogen, or any combination thereof, or (ii) said first gas (13) is composed of a mixture of at least one noble gas with acetylene, methane, ethane and/or one or more other volatile hydrocarbons.

13. An apparatus according to claim 10, wherein said magnets (9) are embedded in said substrate holder (7).

14. An apparatus according to claim 10, wherein at least a portion of said second gas (14) is admitted into said chamber (1) through said hollow cathode (3).

15. An apparatus according to claim 10, wherein said hollow cathode (3) is electrically connected to said first power generator (5) by a first power switch (6), and/or wherein said second power generator (11) is electrically connected to said substrate holder (7) by a second power switch (12).

16. An apparatus according to claim 10, wherein said at least one hollow cathode (3) forms a system shaped to follow surface geometry of said one or more insulator substrates (8).

17. An apparatus according to claim 10, wherein said substrate holder (7) is configured to perform one or more motions with respect to said hollow cathode (3), and wherein said one or more motions include linear motion, rotational motion, stepwise motion, or any combination thereof.

18. An apparatus according to claim 10, wherein said at least one hollow cathode (3) includes a graphite hollow cathode.
